(19) United States
(12) Patent Application Publication
(10) Pub. No.: US 2006/0211173 A1
(43) Pub. Date: Sep. 21, 2006

(54) Package of image sensor device and formation thereof

(75) Inventors: Wei-Min Hsiao, Kaohsiung City (TW); Kuo-Pin Yang, Kaohsiung (TW)

Correspondence Address: Genus Law Group, LLC / Lowe Hauptman & Berner, LLP;Suite 300, 1700 Diagonal Road, Alexandria, VA, 22314, US

(73) Assignee: Advance Semiconductor Engineering Inc.

(21) Appl. No.: 11/336,842

(22) Filed: Jan. 23, 2006

(30) Foreign Application Priority Data
Mar. 18, 2005 (TW) 94108521

(51) Int. Cl. H01L 21/00

(52) U.S. Cl. 438/116

(57) ABSTRACT

A package of CMOS image sensor device and the formation thereof are provided. The package includes a soft layer between an image sensor device and a substrate. The image sensor device has multitudes of conductive structures distributed around a photo-sensing zone. The substrate has multitudes of conductive pads distributed around a transparent zone faced the photo-sensing zone. The photo-sensing zone is within the transparent zone and each conductive pad is corresponding to each conductive structure. A soft layer, the image sensor device and the substrate enclose the photo-sensing zone, transparent zone, conductive structures and pads.

### FIELD OF THE INVENTION

The present invention relates generally to a package of die and formation thereof, and more specifically, to a package of image sensor device and formation thereof.

### DESCRIPTION OF THE PRIOR ART

The technology of semiconductor process had developed to have capability of manufacturing the image sensor device, such as the CMOS image sensor device. The CMOS image sensor device is generally used in many electrical products as it has advantage of smaller volume and cheaper price than the CCD image sensor device, even though the compared basis is the whole package of CMOS image sensor device. However, to enhance application of the CMOS image sensor device, the variant package design is necessary to manage the variant product design. In addition, how to reduce the cost is also a key to improve the application of CMOS image photo device especially while it is used in parity products.

Accordingly, it would be advantageous to have a novel package of image sensor device and its forming method to manage the variant product design and to reduce the cost.

### SUMMARY OF THE INVENTION

It is therefore a general object of the present invention to provide a package of image sensor device and its forming method to accommodate the variant product design.

It is another object of the present invention to provide a package of image sensor device and its forming method, the conventional bonding die to substrate then wiring process is replaced by flipping and eutectic process to reduce the cost.

It is another further object of the present invention to provide a package of image sensor device and its forming method, wherein the conventional gluing or sealing process is replaced by utilizing a soft layer to protect die from the damage of moisture to simplify the process.

According to the objects, the present invention provides a package of image sensor device and its forming method, which includes an image sensor device, a substrate and a soft layer. The image sensor device has multitudes of conductive structures distributed around a photo-sensing zone. The substrate has multitudes of conductive pads distributed around a transparent zone faced the photo-sensing zone. The photo-sensing zone is within the transparent zone and each conductive pad is corresponding to each conductive structure. A soft layer, the image sensor device and the substrate enclose the photo-sensing zone, transparent zone, conductive structures and pads.

### BRIEF DESCRIPTION OF THE DRAWINGS

FIG. 1A to FIG. 1C illustrate the partial side views of a single die formation according to one embodiment of the present invention.

FIG. 2A to FIG. 2C is a sequence of partial section views to show a process forming a singular die package according to one embodiment of the present invention.

FIG. 3 shows a top view of the substrate according to one embodiment of this invention.

### DESCRIPTION OF THE PREFERRED EMBODIMENT

While the present invention will be described with reference to a few specific embodiments, the description is illustrative of the invention and is not to be construed as limiting the invention. Various modifications to the present invention can be made to the preferred embodiments by those skilled in the art without departing from the true spirit and scope of the invention as defined by the appended claims. It will be noted here that well known process steps have not been described in detail in order to not necessarily obscure the present invention.

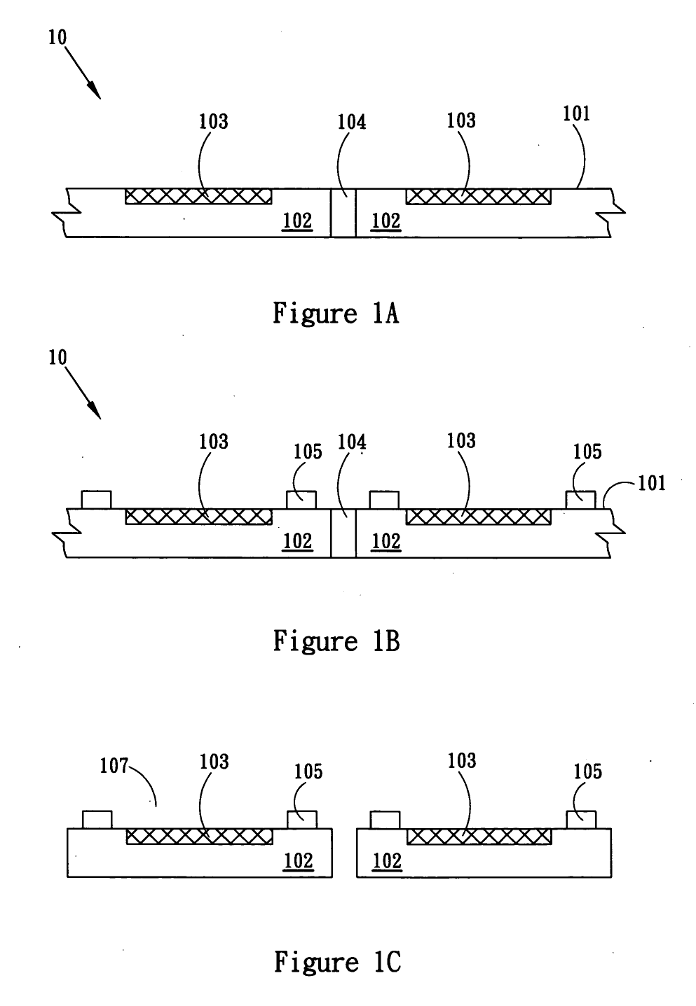

According to one embodiment of the present invention, FIG. 1A to FIG. 1C illustrates diagramed the partial side views of formation of a single die 107. Referring to FIG. 1A, a wafer 10 includes a plural of same functional chips 102 A scribed groove 104 is scribed between each two chips 102 for die singulation. In one embodiment, the chip 102 is a chip having function of photo sensing, such as CMOS photo image sensing chip. Each chip 102 has a photo-sensing zone 103 in its active surface 101, and the photo-sensing zone could be different shapes and dimensions. It will be noted here that dimension of the photo-sensing zone 103 is generally smaller than dimension of the active surface 101, thus the active surface 101 has space to place other component or device.

Referring to FIG. 1B, a plural of first conductive structure 105 is formed by appropriate process to electrically connect other devices or components. In one embodiment, each separated gold bump is distributively formed on each of the active surface 101 near the photo-sensing zone 103. In one preferred embodiment, gold or alloy of gold is employed to form gold bump having the same dimension and is called the first conductive structure 105 here. It will be noted here that a plural of the first conductive structures 105 which formed on the same active surface 101 could be different dimension, and it could be symmetrically formed on periphery or two opposite side of the photo-sensing zone 103. As shown in FIG. 1C, after formed the first conductive structure 105, the wafer 10 is sawn along the scribed groove 104 by well know process to singularize multitudes of dies 107. In one embodiment, the active surface of singular die has one photo-sensing zone whose vicinity had formed several first conductive structures 105.

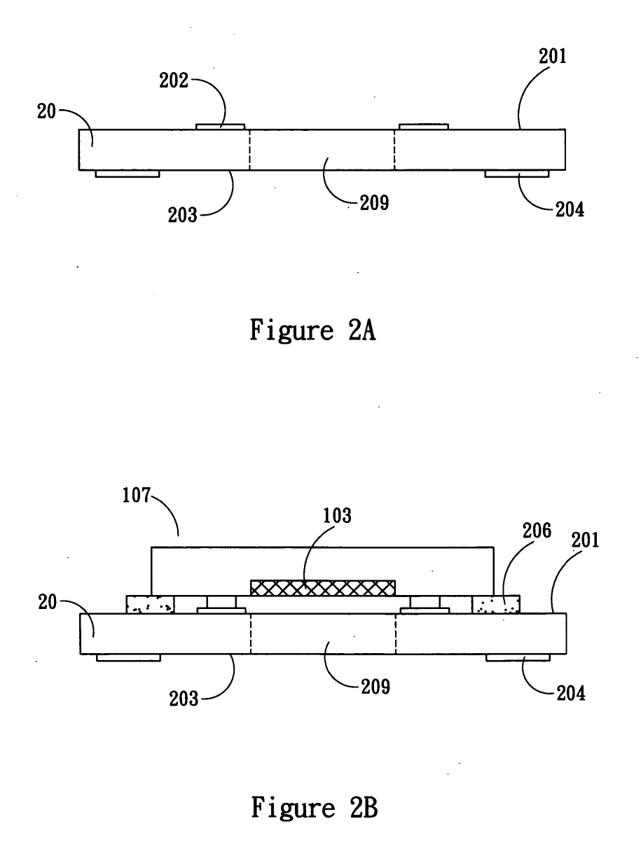

According to one embodiment of the present invention, FIG. 2A to FIG. 2C is a sequence of partial section views to show a process forming a singular die 107. Referring to FIG. 2A, a substrate 20 having a first surface 201 and a second surface 203 is provided. Several first conductive pads 202 are formed on the first surface 201 and several second conductive pads 204 are formed on the second surface 203. In one embodiment, the substrate 20 is a transparent substrate having a transparent zone 209, and it is made of antistatic and transparent materials, such as polyimide. Alternatively, the substrate 20 is opaque, but the transparent zone 209 is also practical by making some opening then fill a transparent material. The transparent zone 209 also functions to isolate the moisture. After that, to form the first conductive pad 202 and the second conductive pad 204 by appropriate process, such as sputtering or electroplating. In a preferred embodiment, the material gold forms the first conductive pad 202 and the material tin forms the second conductive pad 204. It will be noted here that the first conductive pad 202 is employed for attaching the die 107 and the second conductive pad 204 is employed for attaching solder ball later, hence the distribution, material and dimension between the first conductive pad 202 and the second conductive pad 204 may be different.

Referring to FIG. 2B, a soft layer 206 is formed to enclose the first conductive pads 202. The die 107 is flipped above the first surface 201 then attach to the substrate 20. In one embodiment, each first conductive structure 105 located on the die 107 has a first conductive pad 202 located on the first surface 201 at its corresponding position, and they are melted together by the eutectic process while the die 107 is attaching to the substrate 20. The melted metal (such as the eutectic gold bump and gold pad) and the soft layer 206 protect the photo-sensing zone 103 against the external force and the damage of moisture. The photo-sensing zone 103 of the die 107 faces the first surface 201. The soft layer, the die 107, and the substrate 20 enclose the photo-sensing zone, the first conductive structures 105 and the first conductive pads 202. According to spirit of this invention, bonding die to substrate then wiring is replaced by eutectic process of the first conductive structure 105 and the first conductive pad 202, therefore the process is simplified. In addition, gluing or sealing process is replaced by utilizing the soft layer 206 to protect the photo-sensing zone 103, and therefore the process is further simplified. Moreover, by using the substrate 20 having the transparent zone 209 which is corresponding to the photo-sensing zone 103, the light could pierce the substrate 20 from the second surface 203 to the photo-sensing zone 103, hence the package design of photo image products could be more diversified.

Referring to FIG. 2C, by appropriate process such as solder ball mounting process to form the second conductive structure 208. In one embodiment, the tin-lead alloy or lead-free tin is major content of the material to form the second conductive structure 208. In addition, the location of the second conductive pads 204 and the second conductive structures 208 are far enough to avoid obstructing the light passing to the photo-sensing zone 103. It could be understandable that the whole package could be electrically connected to a printed circuit board via the second conductive structure 208 by appropriate process such as SMT (surface mounting technology).

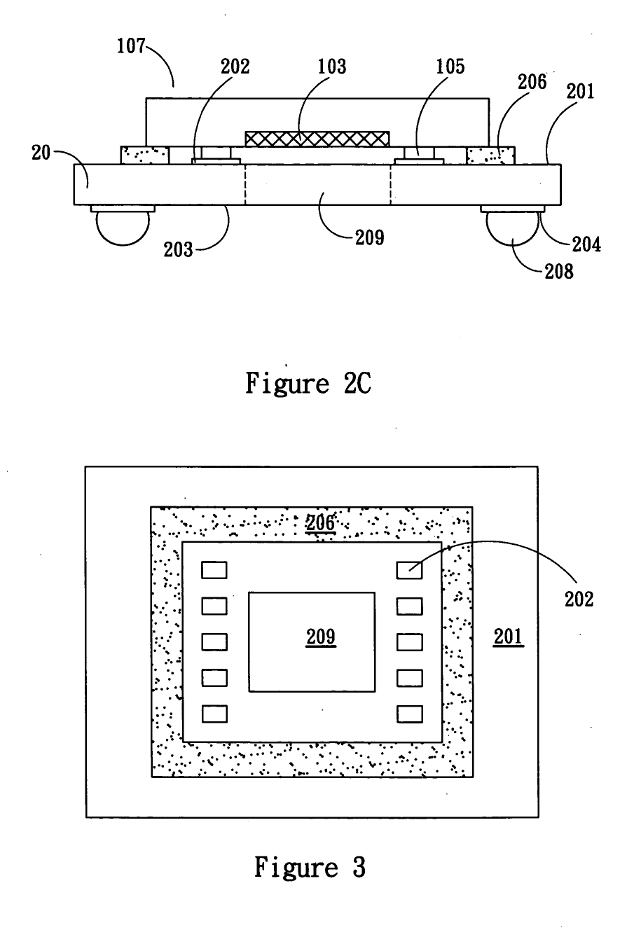

FIG. 3 shows a top view of the substrate 20 according to one embodiment of this invention. Because the transparent zone 209 is employed for supplying the sensing area to the photo-sensing zone 103, so there is no any circuit within it. In addition, ten first conductive pads 202 are symmetrically distributed in the two sides of the transparent zone 209, and the soft layer 206 is formed in the periphery of the first conductive pads 202 and forms a sealing ring.

According to the foregoing disclosure, a package and its formation of image sensor device, which includes an image sensor device, a substrate and a soft layer being provided. The active surface of the image sensor device has a photo-sensing zone and a plural of first conductive structures is near to the photo-sensing zone. The substrate having a transparent zone and a plural of first conductive pads is near to the transparent zone. The first surface of the substrate faces to the active surface of the image sensor device. The transparent zone of the substrate is corresponding to the photo-sensing zone of the image sensor device; the first conductive pad of the substrate is corresponding to the first conductive structure of the image sensor device, and melted together by eutectic process. The soft layer forms a sealing ring between the first surface and the active surface to enclosure the photo-sensing zone, the transparent zone, a plural of first conductive structures, and a plural of first conductive pads. In addition, a plural of second conductive pads/structures is formed in the opposite side of the first surface.

While this invention has been described in terms of several preferred embodiments, there are alteration, permutations, and equivalents which fall within the scope of this invention. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

What is claimed is:

1. A package of image sensor device, comprising:
a image sensor device having an active surface which includes a photo-sensing zone and a plurality of first conductive structures distributed near said photo-sensing zone;
a substrate having a transparent zone and a first surface to face said active surface, wherein a plurality of first conductive pads being distributed near said transparent zone, said photo-sensing zone being within said transparent zone, each of said first conductive structure mounting corresponding said first conductive pad; and
a soft layer located between said active surface and said first surface to form a sealing chamber to enclosure said photo-sensing zone, said transparent zone, said plurality of first conductive structures and said plurality of first conductive pads.

2. The package of image sensor device as set forth in claim 1, wherein said first conductive structures and said first conductive pads are made of a gold-based material.

3. The package of image sensor device as set forth in claim 1, wherein said substrate is a transparent substrate.

4. The package of image sensor device as set forth in claim 1, wherein said substrate comprises a second surface having a plurality of second conductive structures in the opposite side of said first surface.

5. The package of image sensor device as set forth in claim 4, wherein said second conductive structures are made of a tin and lead based material.

6. The package of image sensor device as set forth in claim 4, wherein said second conductive structures are made of a lead-free material.

7. The package of image sensor device as set forth in claim 1, wherein said image sensor device is an image die having said photo-sensing zone.

8. The package of image sensor device as set forth in claim 1, wherein said first conductive structures are separately distributed in the periphery of said photo-sensing zone.

9. The package of image sensor device as set forth in claim 1, wherein said first conductive structures are symmetrically distributed in the two opposite sides of said photo-sensing zone.

10. A method to package the image sensor device, comprising:
providing a image sensor device to have an active surface which includes a photo-sensing zone and a plurality of first conductive structures distributed near said photo-sensing zone;
providing a substrate having a transparent zone and a first surface, wherein a plurality of first conductive pads located on said first surface are distributed near said transparent zone;
forming a soft layer located on said first surface to enclosure said transparent zone and said plurality of first conductive pads; and
melting together each of said first conductive structure and its corresponding said first conductive pad to seal said photo-sensing zone, said transparent zone, said plurality of first conductive structures and said plurality of first conductive pads.

11. The method as set forth in claim 10, further comprising a flipping method to flip said image sensor device to let said active surface facing said first surface.

12. The method as set forth in claim 10, further comprising a flipping method to flip said image sensor device to let said photo-sensing zone facing said transparent zone.

13. The method as set forth in claim 10, further comprising forming a plurality of second conductive pads on a second surface of said substrate, wherein said second surface is the opposite side of said first surface.

14. The method as set forth in claim 13, further comprising forming a second conductive structure on each of said second conductive pad.

15. The method as set forth in claim 10, wherein said providing a image sensor device further comprises a method to form a plurality gold bumps as said plurality first conductive structures.

16. The method as set forth in claim 10, wherein providing a substrate comprises providing a transparent substrate.
